(19) United States
(12) Patent Application Publication
(10) Pub. No.: US 2025/0366372 A1
(43) Pub. Date: Nov. 27, 2025

(54) WAFER FORMATION AND PROCESSING METHOD

(71) Applicant: Taiwan Semiconductor Manufacturing Co., Ltd., Hsinchu (TW)

(72) Inventors: Chung-Jung Wu, Hsinchu (TW); Jui Hsuan Tsai, Taipei (TW); Su-Chun Yang, Hsinchu (TW); Jih-Churng Twu, Hsinchu (TW); Jeng-Nan Hung, Taichung (TW); Chih-Hang Tung, Hsinchu (TW)

(21) Appl. No.: 18/672,646

(22) Filed: May 23, 2024

(51) Int. Cl. H10N 30/072; H10N 30/00; H10N 30/086; H10N 30/50; H10N 30/853

(52) U.S. Cl. CPC H10N 30/072; H10N 30/086; H10N 30/505; H10N 30/708; H10N 30/8542

(57) ABSTRACT

In an embodiment, a method includes bonding a first surface of a first substrate to a second substrate using thermo-compression bonding (TCB) to form a wafer, where the first substrate includes lithium niobate, and the second substrate includes silicon, performing a first annealing process on the wafer at a first temperature, performing a planarization process on a second surface of the first substrate, where the second surface is on an opposite side of the first substrate as the first surface; and performing a second annealing process on the wafer at a second temperature, where the second temperature is greater than the first temperature.

### BACKGROUND

Lithium Niobate (LiNbO₃) is a crystalline material that exhibits electro-optic, piezoelectric, and ferroelectric properties. It can be used for various applications ranging from signal processing to frequency control. It can also be used in the manufacture of non-volatile memory devices and electro-optic modulators. While extensive efforts have been made to integrate the use of (LiNbO₃) with current manufacturing processes, further improvements are still necessary for achieving seamless compatibility within existing production methodologies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate a cross-sectional view and a top-down view of intermediate stages in the manufacturing of a lithium niobate on insulator (LNOI) wafer, in accordance with some embodiments.

FIGS. 2-4 illustrate cross-sectional views of intermediate stages in the manufacturing of a lithium niobate on insulator (LNOI) wafer, in accordance with some embodiments.

FIGS. 5A-5B illustrate cross-sectional views of intermediate stages in the manufacturing of a lithium niobate on insulator (LNOI) wafer, in accordance with other embodiments.

FIGS. 6-11B illustrate cross-sectional views and a top-down view of intermediate stages in the manufacturing of a lithium niobate on insulator (LNOI) wafer, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods applied to, but not limited to, the formation of a lithium niobate on insulator (LNOI) wafer that is compatible with and able to be further processed on 12-inch (also referred to as 300 mm) semiconductor manufacturing tools. The formation of the LNOI wafer comprises bonding a silicon wafer having a first diameter to a lithium niobate (LiNbO₃) substrate having a second diameter, wherein the second diameter is smaller than the first diameter. In an embodiment, the first diameter is equal to 12 inches (also referred to as 300 mm). The lithium niobate substrate is bonded to a first surface of a silicon oxide layer that is disposed on the silicon wafer using thermo-compression (TCB) bonding. The lithium niobate substrate may comprise an implantation layer rich with helium defects. After the bonding of the lithium niobate substrate to the silicon wafer, a first annealing is performed to strengthen the bonding between the lithium niobate substrate and the silicon wafer. A thinning process is then performed on a surface of the lithium niobate substrate to reduce the thickness of the lithium niobate substrate. After the thinning process, a second annealing process is performed to cleave the lithium niobate substrate along the implantation layer, which leaves a thin-film layer of lithium niobate (also referred to subsequently as a lithium niobate layer) on the silicon oxide layer. After the second annealing process, a third annealing process is performed to strengthen the bonding between the lithium niobate layer and the silicon wafer. After the third annealing process, a filling material is formed over the silicon wafer and the lithium niobate layer. A planarization process is then performed to remove excess filling material over the lithium niobate layer and to expose the lithium niobate layer. The remaining filling material, the lithium niobate layer, the silicon wafer, and the silicon oxide layer form the LNOI wafer. Advantageous features of one or more embodiments disclosed herein may include the LNOI wafer being compatible with and being able to be further processed by 12-inch (also referred to as 300 mm) semiconductor manufacturing tools, despite the lithium niobate substrate having the second diameter that is smaller than 12 inches. The 12-inch wafer process is a mature and stable process and the technology and infrastructure for producing devices on 12-inch (also referred to as 300 mm) wafers is well-established and optimized. As a result, the further processing of the LNOI wafer using 12-inch (also referred to as 300 mm) semiconductor manufacturing tools increases manufacturing efficiency and cost-effectiveness, which further results in reduced manufacturing costs per unit and an increased overall production throughput.

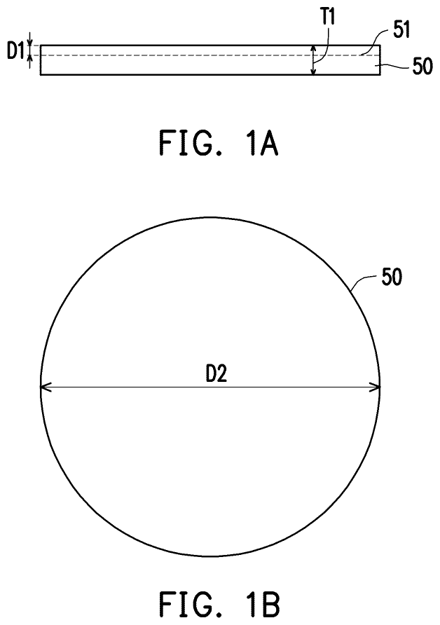

FIGS. 1A through 11B illustrate various top-down views and cross-sectional views during intermediate stages in the formation of a lithium niobate on insulator (LNOI) wafer 10.

FIG. 1A illustrates a cross-sectional view of a substrate 50. FIG. 1B illustrates a top-down view of the substrate 50. The substrate 50 may comprise a ferroelectric material, such as lithium niobate (LiNbO₃), or the like, and may have a thickness T1 that is in a range from 300 μm to 700 μm. In an embodiment, the substrate 50 may comprise an implantation species (or dopants) that are introduced into the substrate 50 through a top surface of the substrate 50 (e.g., through an implantation process). In various embodiments, the implantation species may include ions formed from, helium (He), hydrogen (H), or the like. In an embodiment, when the implantation species is helium, the helium ions form an implantation layer 51 that is rich with helium defects (e.g., in the form of helium atoms). In addition, a portion of the substrate 50 between the top surface of the substrate 50 and the implantation layer 51 may have little or no defects or damage. The implantation layer 51 may be disposed at a depth D1 below the top surface of the substrate 50, wherein the depth D1 is in a range from 10 nm to 1000 nm. In an embodiment, as shown in FIG. 1B, the substrate 50 may have a circular shape when seen in a top-down view. In an embodiment, the substrate 50 may have a diameter D2 that is in a range from 4 inches to 8 inches. In an embodiment, the diameter D2 is less than 12 inches.

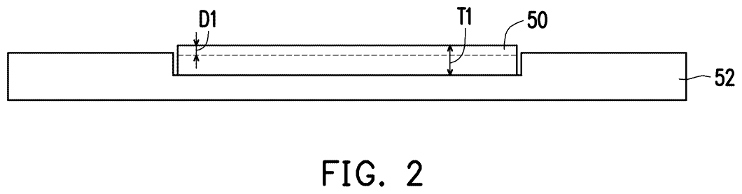

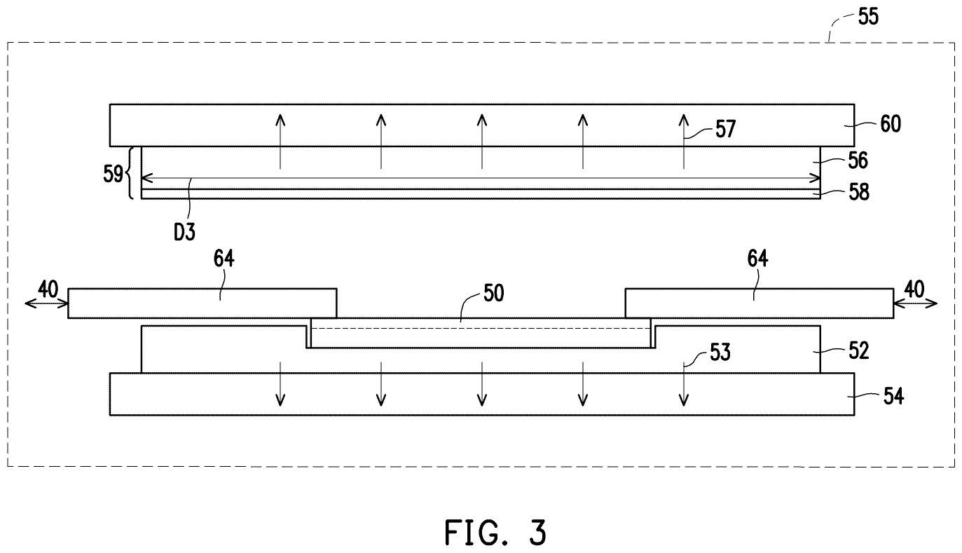

In FIG. 2, the substrate 50 is positioned within a cavity of an adapter-carrier wafer 52. The cavity may be disposed in a central region of the adapter-carrier wafer 52, such that a bottom portion of the substrate 50 is disposed below a topmost surface of the adapter-carrier wafer 52, and a top portion of the substrate 50 protrudes above the topmost surface of the adapter-carrier wafer 52. Gaps may be disposed between sidewalls of the substrate 50 and adjacent sidewalls of the adapter-carrier wafer 52 within the cavity. In an embodiment, the adapter-carrier wafer 52 may comprise silicon, quartz, glass, or the like.

FIG. 3 illustrates a thermo-compression bonding (TCB) apparatus that includes a TCB upper chuck 60 and a TCB bottom chuck 54. The TCB apparatus may be disposed within a bonding chamber 55, wherein a pressure within the bonding chamber 55 may be controllable. The TCB upper chuck 60 may comprise one or more vacuum channels used to create a first vacuum force 57, so that the TCB upper chuck 60 may be used to pick and hold a first workpiece 59 as shown in FIG. 3. The function, position and first vacuum force 57 of the TCB upper chuck 60 may be adjustable which allows for vertical movement of the TCB upper chuck 60. The first workpiece 59 may comprise a semiconductor wafer. The semiconductor wafer may include a substrate 56, which may be crystalline silicon wafer, or the like. A bonding layer 58 is disposed over a surface of the substrate 56. The bonding layer 58 may comprise silicon oxide formed on the surface of the substrate 56 by a deposition process, such as chemical vapor deposition (CVD), physical vapor deposition (PVD), or the like. In other embodiments, the bonding layer 58 may be formed by the thermal oxidation of a silicon surface on the substrate 56. In an embodiment, the first workpiece 59 may have a diameter D3 that is greater than the diameter D2 of the substrate 50. In an embodiment, the diameter D3 is equal to 12 inches (also referred to as 300 mm).

The TCB bottom chuck 54 may comprise one or more vacuum channels used to create a second vacuum force 53, so that the TCB bottom chuck 54 may be used to hold a second workpiece (e.g., the adapter-carrier wafer 52 and the substrate 50 positioned within the cavity in the adapter-carrier wafer 52 that was described previously in FIG. 2) as shown in FIG. 3.

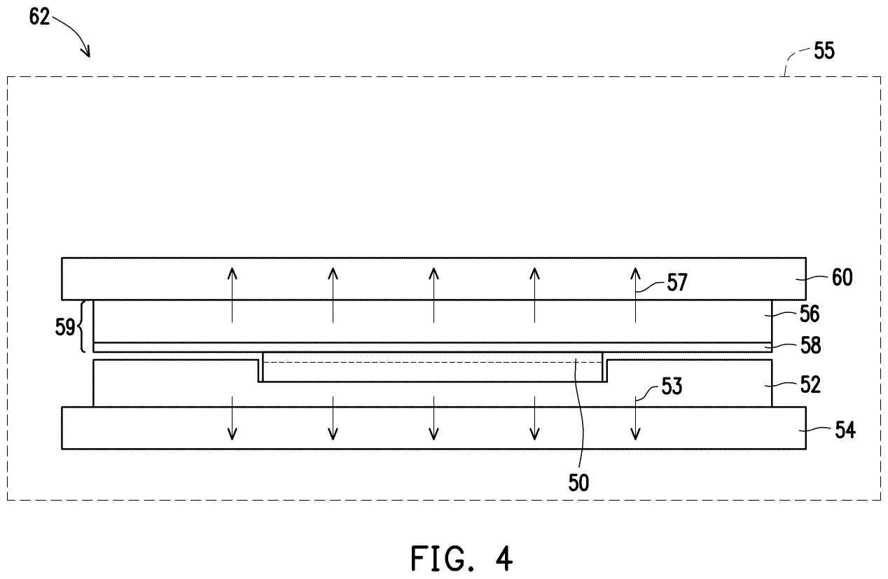

Referring further to FIG. 3, the TCB upper chuck 60 is used to pick and hold the first workpiece 59 such that the bonding layer 58 is facing away from the TCB upper chuck 60 and is facing towards the TCB bottom chuck 54, and the TCB bottom chuck 54 is used to hold the second workpiece (e.g., the adapter-carrier wafer 52 and the substrate 50 positioned within the cavity in the adapter-carrier wafer 52 that was described previously in FIG. 2) such that a bottom surface of the adapter-carrier wafer 52 is in physical contact with the TCB bottom chuck 54. In an embodiment, after the TCB upper chuck 60 is used to pick and hold the first workpiece 59, and the TCB bottom chuck 54 is used to hold the second workpiece (e.g., the adapter-carrier wafer 52 and the substrate 50 positioned within the cavity in the adapter-carrier wafer 52 that was described previously in FIG. 2), one or more spacers 64 may be inserted between the first workpiece 59 and the substrate 50 in order to prevent physical contact between the substrate 50 and the first workpiece 59. In other embodiments, the one or more spacers 64 may not be used and are not inserted between the first workpiece 59 and the substrate 50. The one or more spacers 64 may be inserted into a gap between the first workpiece 59 and the substrate 50 along paths 40 that are parallel to a major surface of the substrate 50, wherein the one or more spacers 64 are inserted starting from the edges of the substrate 50 and moving towards the center of the substrate 50. Each of the one or more spacers 64 is therefore disposed between the first workpiece 59 and edges of the substrate 50. In addition, each of the one or more spacers 64 is disposed between edges of the first workpiece 59 and corresponding edges of the adapter-carrier wafer 52. Prior to a thermo-compression bonding (TCB) process 62 (described subsequently in FIG. 4), the one or more spacers 64 may be removed from between the first workpiece 59 and the substrate 50 along the paths 40, by moving out the one or more spacers 64 along the paths 40 and away from the center and the edges of the substrate 50.

In FIG. 4, a thermo-compression bonding (TCB) process 62 is performed using the TCB apparatus described previously in FIG. 3. During the TCB process 62, the bonding chamber 55 may be evacuated to reduce a pressure within the bonding chamber 55 to vacuum. For example, a pressure within the bonding chamber 55 during the TCB process 62 may be in a range from 1 torr to 1×10⁻⁸ torr. During the TCB process 62, the one or more spacers 64 (if present) are removed, and the TCB upper chuck 60 is used to place the first workpiece 59 on the second workpiece (e.g., the adapter-carrier wafer 52 and the substrate 50 described previously in FIGS. 2-3), such that the bonding layer 58 of the first workpiece 59 is in physical contact with the top surface of the substrate 50. After the placement of the first workpiece 59 on the adapter-carrier wafer 52 and the substrate 50, pressure is exerted by the TCB upper chuck 60 and/or the TCB bottom chuck 54 to promote intimate contact between the bonding layer 58 and the top surface of the substrate 50. For example, during the TCB process 62, a compression force that may be in a range from 100 N to 50000 N may be applied by the TCB upper chuck 60 and/or the TCB bottom chuck 54 to push the first workpiece 59 and the second workpiece (e.g., the adapter-carrier wafer 52 and the substrate 50) together. During the TCB process 62, when the bonding layer 58 and the top surface of the substrate 50 are in physical contact, a gap may be disposed between the bonding layer 58 and the adapter-carrier wafer 52, such that the adapter-carrier wafer 52 and the bonding layer 58 are not in physical contact.

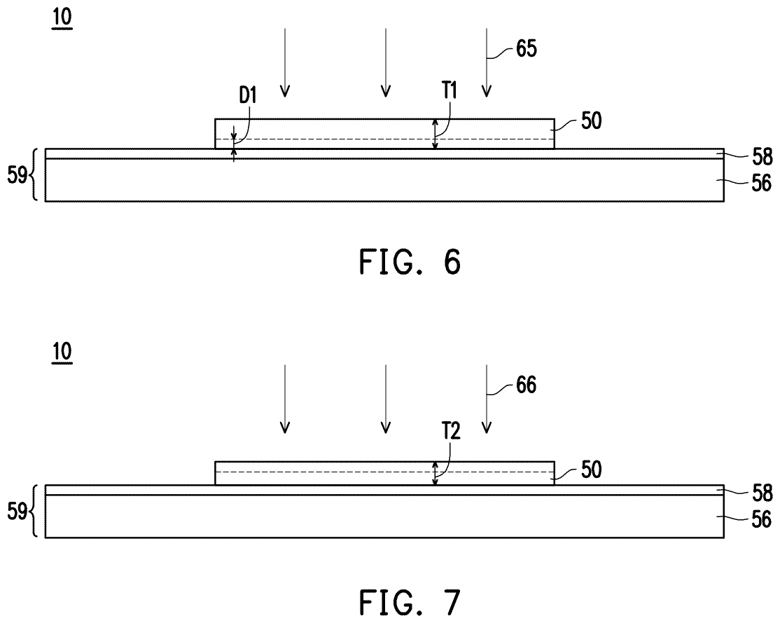

During the TCB process 62, heat may be supplied by a heat source integrated into the TCB apparatus described in FIGS. 3-4. In an embodiment, the heat source may include one or more resistive heating elements (not shown in the Figures) disposed in the TCB upper chuck 60 and/or the TCB bottom chuck 54, wherein each resistive heating element generates heat due to the resistance of the material of the heating element as an electrical current passes through the resistive heating element. In an embodiment, the heat source may include coils (not shown in the Figures) disposed in the TCB upper chuck 60 and/or the TCB bottom chuck 54 that heat up when electrical current(s) flows through the coils. In an embodiment, the heat source may heat up the TCB upper chuck 60 and/or the TCB bottom chuck 54 to a temperature that is in a range from 25° C. to 180° C. The supplied heat is used to elevate a temperature of the bonding interface between the substrate 50 and the bonding layer 58 to allow for effective diffusion of atoms from the silicon oxide surface of the bonding layer 58 and the lithium niobate surface of the substrate 50 into each other. As a result oxide-to-oxide bonds may be formed at the interface between the substrate 50 and the bonding layer 58, resulting in the substrate 56 being bonded to the substrate 50 to form the LNOI wafer 10 (shown subsequently in FIG. 6). In an embodiment, the bonding layer 58 may function as the insulator layer of the LNOI wafer 10. In an embodiment, the TCB process 62 (e.g., which includes supplying heat from the heat source to the TCB upper chuck 60 and/or the TCB bottom chuck 54 as described above, and which includes applying the compression force by the TCB upper chuck 60 and/or the TCB bottom chuck 54 to push the first workpiece 59 and the second workpiece (e.g., the adapter-carrier wafer 52 and the substrate 50) together as described above) may be performed for a duration that is in a range from 1 minute to 60 minutes. As shown subsequently in FIG. 6, after the TCB process 62 is performed, the substrate 50 and the substrate 56 that comprise the LNOI wafer 10 are separated from the adapter-carrier wafer 52 and removed from the TCB apparatus.

Advantages can be achieved by performing the TCB process 62 using the TCB apparatus described above in FIGS. 3-4, wherein during the TCB process 62, the TCB upper chuck 60 is used to place the first workpiece 59 on the second workpiece (e.g., including the adapter-carrier wafer 52) such that the bonding layer 58 of the first workpiece 59 is in physical contact with the top surface of the substrate 50. These advantages include the use of the second workpiece that comprises the adapter-carrier wafer 52 and the substrate 50 disposed in the cavity in the adapter-carrier wafer 52 allowing for uniform distribution of applied compression force and heat from the heat source to a bottom surface of the substrate 50 during the TCB process 62. As a result, improved bonding can be achieved along the bonding interface between the substrate 50 and the bonding layer 58.

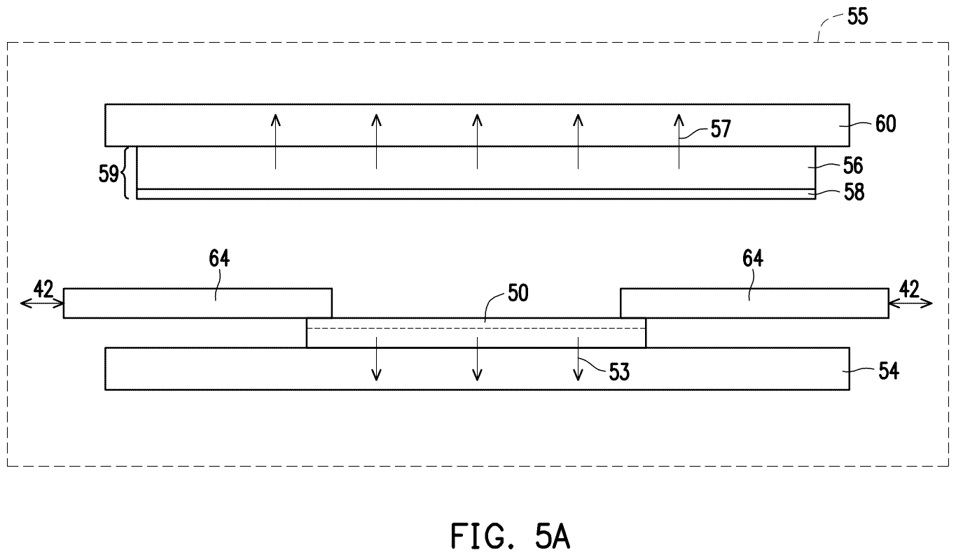

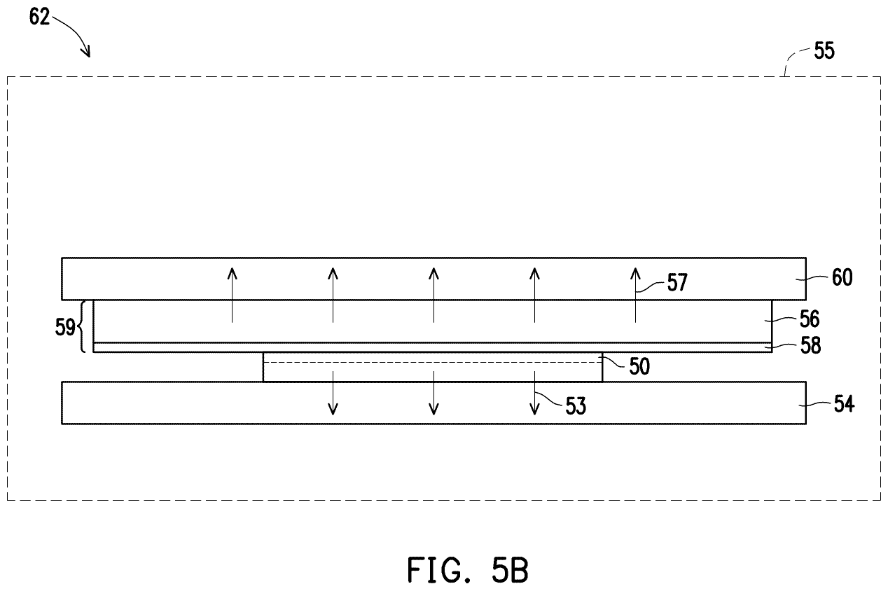

FIGS. 5A-5B illustrates the TCB process 62 in accordance with some other embodiments. Unless specified otherwise, like reference numerals in this embodiment (and subsequently discussed embodiments) represent like components in the embodiment shown in FIGS. 1A through 4 formed by like processes. Accordingly, the process steps and applicable materials may not be repeated herein.

FIG. 5A illustrates the thermo-compression bonding (TCB) apparatus that includes the TCB upper chuck 60 and the TCB bottom chuck 54 that was described previously in FIGS. 3-4. The TCB upper chuck 60 may comprise one or more vacuum channels used to create the first vacuum force 57, so that the TCB upper chuck 60 may be used to pick and hold the first workpiece 59 as shown in FIG. 5A. The TCB bottom chuck 54 may comprise one or more vacuum channels used to create the second vacuum force 53, so that the TCB bottom chuck 54 may be used to hold a second workpiece. The embodiment shown in FIGS. 5A-5B is different from the embodiment shown in FIGS. 3-4 in that the second workpiece of the embodiment shown in FIGS. 5A-B only comprises the substrate 50. The second workpiece of the embodiment shown in FIGS. 5A-5B does not therefore comprise the adapter-carrier wafer 52 that was shown previously in the embodiment of FIGS. 2 through 4.

Referring further to FIG. 5A, the TCB upper chuck 60 is used to pick and hold the first workpiece 59 such that the bonding layer 58 is facing away from the TCB upper chuck 60 and is facing towards the TCB bottom chuck 54, and the TCB bottom chuck 54 is used to hold the substrate 50 such that a bottom surface of the substrate 50 is in physical contact with the TCB bottom chuck 54. In an embodiment, after the TCB upper chuck 60 is used to pick and hold the first workpiece 59, and the TCB bottom chuck 54 is used to hold the substrate 50, the one or more spacers 64 may be inserted between the first workpiece 59 and the substrate 50 in order to prevent physical contact between the substrate 50 and the first workpiece 59. In other embodiments, the one or more spacers 64 may not be used and are not inserted between the first workpiece 59 and the substrate 50. The one or more spacers 64 may be inserted into a gap between the first workpiece 59 and the substrate 50 along paths 42 that are parallel to a major surface of the substrate 50, wherein the one or more spacers 64 are inserted starting from the edges of the substrate 50 and moving towards the center of the substrate 50. Each of the one or more spacers 64 is therefore disposed between the first workpiece 59 and edges of the substrate 50. Prior to the TCB process 62 (described subsequently in FIG. 5B), the one or more spacers 64 may be removed from between the first workpiece 59 and the substrate 50 along the paths 42, by moving out the one or more spacers 64 along the paths 42 and away from the center and the edges of the substrate 50.

In FIG. 5B, the TCB process 62 is performed using the TCB apparatus described previously in FIGS. 3-4. During the TCB process 62, the bonding chamber 55 may be evacuated to reduce a pressure within the bonding chamber 55 to vacuum. For example, a pressure within the bonding chamber 55 during the TCB process 62 may be in a range from 1 torr to 1×10⁻⁸ torr. During the TCB process 62, the one or more spacers 64 (if present) are removed, and the TCB upper chuck 60 is used to place the first workpiece 59 on the substrate 50 such that the bonding layer 58 of the first workpiece 59 is in physical contact with the top surface of the substrate 50. After the placement of the first workpiece 59 on the substrate 50, pressure is exerted by the TCB upper chuck 60 and/or the TCB bottom chuck 54 to promote intimate contact between the bonding layer 58 and the top surface of the substrate 50. For example, during the TCB process 62, a compression force that may be in a range from 100 N to 50000 N may be applied by the TCB upper chuck 60 and/or the TCB bottom chuck 54 to push the first workpiece 59 and the substrate 50 together.

During the TCB process 62, heat may be supplied by a heat source integrated into the TCB apparatus as described previously in FIG. 4 above. In an embodiment, the heat source may heat up the TCB upper chuck 60 and/or the TCB bottom chuck 54 to a temperature that is in a range from 25° C. to 180° C. The supplied heat is used to elevate a temperature of the bonding interface between the substrate 50 and the bonding layer 58 to allow for effective diffusion of atoms from the silicon oxide surface of the bonding layer 58 and the lithium niobate surface of the substrate 50 into each other. As a result oxide-to-oxide bonds may be formed at the interface between the substrate 50 and the bonding layer 58, resulting in the substrate 56 being bonded to the substrate 50 to form the LNOI wafer 10 (shown subsequently in FIG. 6). In an embodiment, the TCB process 62 (e.g., which includes supplying heat from the heat source to the TCB upper chuck 60 and/or the TCB bottom chuck 54 as described above, and which includes applying the compression force by the TCB upper chuck 60 and/or the TCB bottom chuck 54 to push the first workpiece 59 and the substrate 50 together as described above) may be performed for a duration that is in a range from 1 minute to 60 minutes. As shown subsequently in FIG. 6, after the TCB process 62 is performed, the substrate 50 and the substrate 56 that comprise the LNOI wafer 10 are removed from the TCB apparatus.

FIG. 6 illustrates a first annealing process 65 that is performed on the LNOI wafer 10 after the bonding of the first workpiece 59 to the substrate 50 as described previously in the embodiments of FIGS. 2 through 4 or the embodiments of FIGS. 5A-B. In an embodiment, the first annealing process 65 may be performed at a temperature that is in a range from 80° C. to 130° C. In an embodiment, the first annealing process 65 may be performed for a duration of time that is in a range from 10 to 720 minutes. Advantages can be achieved by performing the first annealing process 65 on the LNOI wafer 10. These advantages include the first annealing process 65 promoting increased inter-diffusion of atoms at the bonding interface between the bonding layer 58 and the substrate 50, which promotes the formation of strong covalent bonds across the bonded interface. As a result, improved bonding can be achieved along the bonding interface between the substrate 50 and the bonding layer 58, which results in a reduction of a risk of delamination of the substrate 50 from the bonding layer 58 during a subsequent thinning process 66.

In FIG. 7, after the first annealing process 65, the thinning process 66 is performed on the LNOI wafer 10, such as on an exposed surface of the substrate 50. The exposed surface of the substrate 50 may be a first surface of the substrate 50 that is opposite a second surface of the substrate 50, wherein the second surface of the substrate 50 is in physical contact with the bonding layer 58. The thinning process 66 may be a planarization process (e.g., a mechanical grinding process, or the like), that is used to reduce a thickness of the substrate 50. In an embodiment, after the thinning process 66 is performed, a thickness T2 of the substrate 50 is in a range from 5 μm to 40 μm.

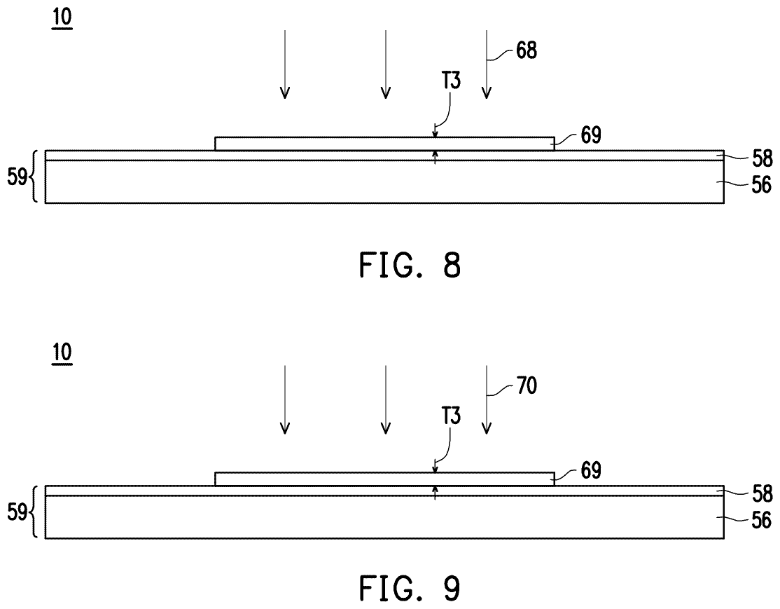

In FIG. 8, after the thinning process 66, a second annealing process 68 is performed on the LNOI wafer 10. During the second annealing process 68, helium in the implantation layer 51 forms bubbles that result in the cleavage of the substrate 50 along the implantation layer 51. This therefore results in the removal of a portion of the substrate 50 from the LNOI wafer 10, and the thinning of the substrate 50, and leaves a thin-film layer 69 that comprises lithium niobate (LiNbO₃) disposed on the bonding layer 58. In an embodiment, after the second annealing process 68 is performed, a thickness T3 of the thin-film layer 69 is in a range from 10 nm to 1000 nm. In an embodiment, the second annealing process 68 may be performed at a temperature that is higher than a temperature at which the first annealing process 65 is performed. In an embodiment, the second annealing process 68 may be performed at a temperature that is in a range from 180° C. to 250° C. In an embodiment, the second annealing process 68 may be performed for a duration of time that is in a range from 10 to 120 minutes.

In FIG. 9, after the second annealing process 68, a third annealing process 70 is performed on the LNOI wafer 10. In an embodiment, the third annealing process 70 may be performed at a temperature that is higher than a temperature at which the first annealing process 65 is performed. In an embodiment, the third annealing process 70 may be performed at a temperature that is in a range from 180° C. to 250° C. In an embodiment, the third annealing process 70 may be performed for a duration of time that is in a range from 30 to 1440 minutes. The third annealing process 70 enhances the bonding strength at the bonding interface between the thin-film layer 69 and the bonding layer 58.

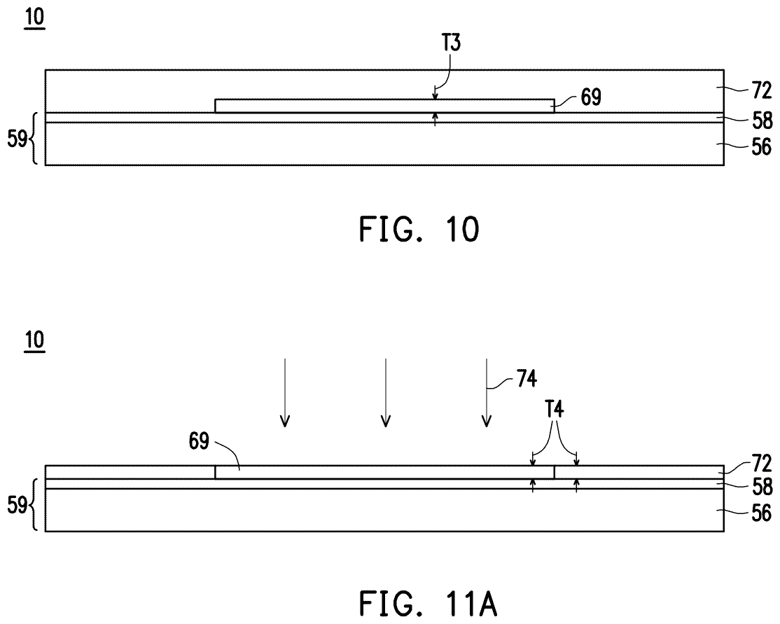

In FIG. 10, after the third annealing process 70 is performed, a filling material 72 may be optionally formed over the thin-film layer 69 and the bonding layer 58. In an embodiment, the filling material 72 may comprise a polymer such as polybenzoxazole (PBO), polyimide, benzocyclobutene (BCB), or the like. In other embodiments, the filling material 72 may be formed of a dielectric material that may comprise a nitride such as silicon nitride; an oxide such as silicon oxide, phosphosilicate glass (PSG), borosilicate glass (BSG), boron-doped phosphosilicate glass (BPSG), or the like; or the like. The filling material 72 may be formed by any acceptable deposition process, such as spin coating, printing, molding, CVD, laminating, the like, or a combination thereof. In an embodiment, after the formation of the filling material 72, a suitable curing process may be performed in order to solidify and strengthen the filling material 72.

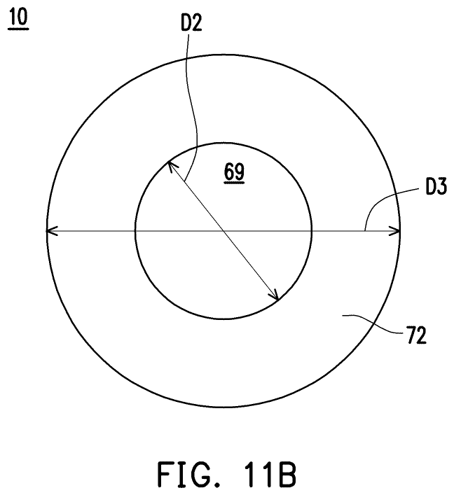

In FIG. 11A, a planarization process 74 may be performed on the filling material 72 (if present) to expose the thin-film layer 69. The planarization process 74 may remove excess material of the filling material 72 over the thin-film layer 69. In addition, the planarization process 74 may be used to planarize a top surface of the thin-film layer 69. After the planarization process 74 is performed, the top surface of the thin-film layer 69 and a top surface of the filling material 72 may be substantially coplanar within process variations. In an embodiment, after the planarization process 74 is performed, a thickness T4 of the thin-film layer 69 and the filling material 72 is in a range from 10 nm to 1000 nm. In an embodiment in which the filling material 72 is not present, the planarization process 74 is only used to planarize the top surface of the thin-film layer 69. The planarization process 74 may be, for example, a chemical-mechanical polish (CMP), or the like. In an embodiment, after the planarization process 74 is performed, an average roughness (Ra) of the top surface of the thin-film layer 69 is less than 20 nm.

Advantages can be achieved by bonding the first workpiece 59 to the substrate 50 using the TCB process 62, performing the first annealing process 65 on the LNOI wafer 10, performing the thinning process 66 on the substrate 50 to reduce the thickness of the substrate 50 to the thickness T2 that is in a range from 5 μm to 40 μm, and performing the second annealing process 68 that removes a portion of the substrate 50 from the LNOI wafer 10 to further thin the substrate 50 and leave the thin-film layer 69 that comprises lithium niobate (LiNbO₃) disposed on the bonding layer 58. The thin-film layer 69 may have the thickness T3 that is in a range from 10 nm to 1000 nm. The first workpiece 59 may have the diameter D3 that is greater than the diameter D2 of the substrate 50, wherein the diameter D3 is equal to 12 inches. The third annealing process 70 is performed on the LNOI wafer 10 after the second annealing process 68 is performed, and the filling material 72 is then formed over the thin-film layer 69 and the bonding layer 58. The planarization process 74 is then performed on the filling material 72 and the thin-film layer 69, wherein, after the planarization process 74 is performed, the top surface of the thin-film layer 69 and the top surface of the filling material 72 may be substantially coplanar. These advantages include the LNOI wafer 10 being compatible with and being able to be further processed by 12-inch (also referred to as 300 mm) semiconductor manufacturing tools, despite the substrate 50 having the diameter D2 that is smaller than 12 inches. The 12-inch wafer process is a mature and stable process and the technology and infrastructure for producing devices on 12-inch (also referred to as 300 mm) wafers is well-established and optimized. As a result, the further processing of the LNOI wafer 10 using 12-inch (also referred to as 300 mm) semiconductor manufacturing tools is enabled, which increases manufacturing efficiency and cost-effectiveness, and which further results in reduced manufacturing costs per unit and an increased overall production throughput.

FIG. 11B illustrates a top-down view of the LNOI wafer 10 after the planarization process 74 is performed. In an embodiment, the LNOI wafer 10 has the diameter D3, wherein the diameter D3 is greater than the diameter D2 of the thin-film layer 69. In an embodiment, the diameter D2 has a diameter that is in a range from 4 to 8 inches. In an embodiment, the diameter D3 is equal to 12 inches.

The embodiments of the present disclosure have some advantageous features. The embodiments provide methods applied to the formation of a lithium niobate on insulator (LNOI) wafer that is compatible with and able to be further processed on 12-inch (also referred to as 300 mm) semiconductor manufacturing tools. The formation of the LNOI wafer comprises bonding a silicon wafer having a first diameter to a lithium niobate (LiNbO₃) substrate having a second diameter, wherein the second diameter is smaller than the first diameter. In an embodiment, the first diameter is equal to 12 inches (also referred to as 300 mm). The lithium niobate substrate is bonded to a first surface of a silicon oxide layer that is disposed on the silicon wafer using thermo-compression (TCB) bonding. The lithium niobate substrate may comprise an implantation layer rich with helium defects. After the bonding of the lithium niobate substrate to the silicon wafer, a first annealing is performed to strengthen the bonding between the lithium niobate substrate and the silicon wafer. A thinning process is then performed on a surface of the lithium niobate substrate to reduce the thickness of the lithium niobate substrate. After the thinning process, a second annealing process is performed to cleave the lithium niobate substrate along the implantation layer, which leaves a thin-film layer of lithium niobate (also referred to subsequently as a lithium niobate layer) on the silicon oxide layer. After the second annealing process, a third annealing process is performed to strengthen the bonding between the lithium niobate layer and the silicon wafer. After the third annealing process, a filling material is formed over the silicon wafer and the lithium niobate layer. A planarization process is then performed to remove excess filling material over the lithium niobate layer and to expose the lithium niobate layer. The remaining filling material, the lithium niobate layer, the silicon wafer, and the silicon oxide layer form the LNOI wafer. These advantages include the LNOI wafer being compatible with and being able to be further processed by 12-inch (also referred to as 300 mm) semiconductor manufacturing tools, despite the lithium niobate substrate having the second diameter that is smaller than 12 inches. The 12-inch wafer process is a mature and stable process and the technology and infrastructure for producing devices on 12-inch (also referred to as 300 mm) wafers is well-established and optimized. As a result, the further processing of the LNOI wafer using 12-inch (also referred to as 300 mm) semiconductor manufacturing tools increases manufacturing efficiency and cost-effectiveness, which further results in reduced manufacturing costs per unit and an increased overall production throughput.

In accordance with an embodiment, a method includes bonding a first surface of a first substrate to a second substrate using thermo-compression bonding (TCB) to form a wafer, where the first substrate includes lithium niobate, and the second substrate includes silicon; performing a first annealing process on the wafer at a first temperature; performing a planarization process on a second surface of the first substrate, where the second surface is on an opposite side of the first substrate as the first surface; and performing a second annealing process on the wafer at a second temperature, where the second temperature is greater than the first temperature. In an embodiment, a diameter of the second substrate is greater than a diameter of the first substrate. In an embodiment, performing the second annealing process includes reducing a thickness of the first substrate to leave a thin-film layer disposed on the second substrate, where the thin-film layer includes lithium niobate. In an embodiment, the method further includes forming a filling material over the second substrate and the thin-film layer; and planarizing the filling material and the thin-film layer, where after planarizing the filling material and the thin-film layer, a top surface of the thin-film layer and a top surface of the filling material are level. In an embodiment, after planarizing the filling material and the thin-film layer, a thickness of the thin-film layer is in a range from 10 nm to 1000 nm. In an embodiment, after planarizing the filling material and the thin-film layer, an average roughness (Ra) of the top surface of the thin-film layer is less than 20 nm. In an embodiment, the first substrate has a thickness that is in a range from 300 μm to 700 μm. In an embodiment, the first substrate includes an implantation layer that includes helium atoms.

In accordance with an embodiment, a method includes attaching a first workpiece to a thermo-compression bonding (TCB) upper chuck of a TCB apparatus, the first workpiece including a semiconductor substrate and a silicon oxide layer over the semiconductor substrate; attaching a second workpiece to a TCB bottom chuck of the TCB apparatus, the second workpiece including a first substrate, where the first substrate includes lithium niobate; performing a TCB process using the TCB apparatus to bond a first surface of the first substrate to the first workpiece to form a wafer; performing a first annealing process on the wafer at a first temperature; and performing a second annealing process on the wafer at a second temperature, where the second temperature is different from the first temperature. In an embodiment, the second workpiece further includes an adapter-carrier wafer, where during attaching the second workpiece to the TCB bottom chuck of the TCB apparatus, the first substrate is disposed in a cavity within the adapter-carrier wafer. In an embodiment, performing the TCB process includes initiating contact between the first surface of the first substrate and the silicon oxide layer, and where during performing the TCB process, a temperature of the TCB upper chuck or the TCB bottom chuck is in a range from 25° C. to 180° C. In an embodiment, performing the TCB process includes applying a compression force that is in a range from 100 N to 50000 N using the TCB upper chuck or the TCB bottom chuck to push the first workpiece and the second workpiece together. In an embodiment, a diameter of the first substrate is smaller than a diameter of the first workpiece, and where the diameter of the first substrate is in a range from 4 inches to 8 inches. In an embodiment, performing the second annealing process on the wafer includes reducing a thickness of the first substrate to leave a thin-film layer disposed on the first workpiece, where the thin-film layer includes lithium niobate. In an embodiment, the method further includes after performing the first annealing process, and before performing the second annealing process, performing a planarization process on a second surface of the first substrate, where the second surface is on an opposite side of the first substrate as the first surface.

In accordance with an embodiment, a method includes bonding a first surface of a first substrate to a second substrate using thermo-compression bonding (TCB) to form a wafer, where a first diameter of the first substrate is smaller than a second diameter of the second substrate, where the first substrate includes lithium niobate, and where the first substrate includes an implantation layer that includes helium atoms; performing a first annealing process on the wafer at a first temperature; performing a first thinning process on a second surface of the first substrate of the wafer, where the second surface is on an opposite side of the first substrate as the first surface; and after performing the first thinning process, performing a second thinning process to cleave a portion of the first substrate along the implantation layer and reduce a thickness of the first substrate. In an embodiment, performing the second thinning process includes performing a second annealing process on the wafer at a second temperature. In an embodiment, the second temperature is greater than the first temperature. In an embodiment, after the first thinning process, a thickness of the first substrate is in a range from 5 μm to 40 μm. In an embodiment, the first annealing process is performed for a first duration of time, and the second annealing process is performed for a second duration of time, where the first duration of time is greater than the second duration of time.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a first surface of a first substrate to a second substrate using thermo-compression bonding (TCB) to form a wafer, wherein the first substrate comprises lithium niobate, and the second substrate comprises silicon;
performing a first annealing process on the wafer at a first temperature;
performing a planarization process on a second surface of the first substrate, wherein the second surface is on an opposite side of the first substrate as the first surface; and
performing a second annealing process on the wafer at a second temperature, wherein the second temperature is greater than the first temperature.

2. The method of claim 1, wherein a diameter of the second substrate is greater than a diameter of the first substrate.

3. The method of claim 1, wherein performing the second annealing process comprises reducing a thickness of the first substrate to leave a thin-film layer disposed on the second substrate, wherein the thin-film layer comprises lithium niobate.

4. The method of claim 3, further comprising:
forming a filling material over the second substrate and the thin-film layer; and
planarizing the filling material and the thin-film layer, wherein after planarizing the filling material and the thin-film layer, a top surface of the thin-film layer and a top surface of the filling material are level.

5. The method of claim 4, wherein after planarizing the filling material and the thin-film layer, a thickness of the thin-film layer is in a range from 10 nm to 1000 nm.

6. The method of claim 4, wherein after planarizing the filling material and the thin-film layer, an average roughness (Ra) of the top surface of the thin-film layer is less than 20 nm.

7. The method of claim 1, wherein the first substrate has a thickness that is in a range from 300 μm to 700 μm.

8. The method of claim 1, wherein the first substrate comprises an implantation layer that includes helium atoms.

9. A method comprising:
attaching a first workpiece to a thermo-compression bonding (TCB) upper chuck of a TCB apparatus, the first workpiece comprising a semiconductor substrate and a silicon oxide layer over the semiconductor substrate;
attaching a second workpiece to a TCB bottom chuck of the TCB apparatus, the second workpiece comprising a first substrate, wherein the first substrate comprises lithium niobate;
performing a TCB process using the TCB apparatus to bond a first surface of the first substrate to the first workpiece to form a wafer;
performing a first annealing process on the wafer at a first temperature; and
performing a second annealing process on the wafer at a second temperature, wherein the second temperature is different from the first temperature.

10. The method of claim 9, wherein the second workpiece further comprises an adapter-carrier wafer, wherein during attaching the second workpiece to the TCB bottom chuck of the TCB apparatus, the first substrate is disposed in a cavity within the adapter-carrier wafer.

11. The method of claim 9, wherein performing the TCB process comprises initiating contact between the first surface of the first substrate and the silicon oxide layer, and wherein during performing the TCB process, a temperature of the TCB upper chuck or the TCB bottom chuck is in a range from 25° C. to 180° C.

12. The method of claim 11, wherein performing the TCB process comprises applying a compression force that is in a range from 100 N to 50000 N using the TCB upper chuck or the TCB bottom chuck to push the first workpiece and the second workpiece together.

13. The method of claim 9, wherein a diameter of the first substrate is smaller than a diameter of the first workpiece, and wherein the diameter of the first substrate is in a range from 4 inches to 8 inches.

14. The method of claim 9, wherein performing the second annealing process on the wafer comprises reducing a thickness of the first substrate to leave a thin-film layer disposed on the first workpiece, wherein the thin-film layer comprises lithium niobate.

15. The method of claim 9, further comprising:
after performing the first annealing process, and before performing the second annealing process, performing a planarization process on a second surface of the first substrate, wherein the second surface is on an opposite side of the first substrate as the first surface.

16. A method comprising:
bonding a first surface of a first substrate to a second substrate using thermo-compression bonding (TCB) to form a wafer, wherein a first diameter of the first substrate is smaller than a second diameter of the second substrate, wherein the first substrate comprises lithium niobate, and wherein the first substrate comprises an implantation layer that includes helium atoms;
performing a first annealing process on the wafer at a first temperature;
performing a first thinning process on a second surface of the first substrate of the wafer, wherein the second surface is on an opposite side of the first substrate as the first surface; and
after performing the first thinning process, performing a second thinning process to cleave a portion of the first substrate along the implantation layer and reduce a thickness of the first substrate.

17. The method of claim 16, wherein performing the second thinning process comprises performing a second annealing process on the wafer at a second temperature.

18. The method of claim 17, wherein the second temperature is greater than the first temperature.

19. The method of claim 17, wherein after the first thinning process, a thickness of the first substrate is in a range from 5 μm to 40 μm.

20. The method of claim 17, wherein the first annealing process is performed for a first duration of time, and the second annealing process is performed for a second duration of time, wherein the first duration of time is greater than the second duration of time.
